(19) United States
(12) Patent Application Publication
(10) Pub. No.: US 2025/0185260 A1
(43) Pub. Date: Jun. 5, 2025

(54) MEMORY DEVICE INCLUDING POWER GATING SWITCH

(71) Applicant: SAMSUNG ELECTRONICS CO., LTD., SUWON-SI (KR)

(72) Inventors: Sanghoon Jung, Suwon-si (KR); Yeongwoo Kang, Suwon-si (KR); Youngseok Park, Suwon-si (KR); Hyunchul Yoon, Suwon-si (KR); Changyoung Lee, Suwon-si (KR); Jeongdon Ihm, Suwon-si (KR)

(21) Appl. No.: 18/779,407

(22) Filed: Jul. 22, 2024

(30) Foreign Application Priority Data
Nov. 30, 2023 (KR) 10-2023-0171840

(51) Int. Cl. H10B 80/00; G11C 11/4074; H01L 23/00; H01L 25/065; H01L 25/18; H10B 12/00

(52) U.S. Cl. CPC H10B 80/00; G11C 11/4074; H01L 24/08; H01L 25/0657; H01L 25/18; H10B 12/315; H10B 12/50; H01L 2224/08145; H01L 2924/1431; H01L 2924/1436

(57) ABSTRACT

A memory device includes a core peripheral circuit structure including a first bonding metal pad connected to an internal power supply voltage line; and a cell array structure disposed on the core peripheral circuit structure and including a second bonding metal pad in contact with the first bonding metal pad. The cell array structure includes a memory cell array and a power gating switch connected between an external power supply voltage line and the first bonding metal pad, and the power gating switch is located in a region of the cell array structure different from a memory cell array and selectively provides an external power supply voltage to the internal power supply voltage line.

### CROSS-REFERENCE TO RELATED APPLICATION

This application is based on and claims priority under 35 USC § 119 to Korean Patent Application No. 10-2023-0171840, filed on Nov. 30, 2023, in the Korean Intellectual Property Office, the disclosure of which is incorporated by reference herein in its entirety.

### BACKGROUND

### 1. Technical Field

The inventive concept relates to semiconductor memory devices, and more particularly, to memory devices in which a power gating switch is located in region of a cell array structure different from a memory cell region.

### 2. Discussion of Related Art

As the power consumption of electronic devices becomes more important, demand for energy efficient electronic devices is increasing. Memory system power, as a portion of a power budget of electronic devices, may account for a significant portion of overall system power usage. Memory systems may include, for example, dynamic random access memory (DRAM) implemented on multiple individual DRAM chips.

Various power-saving methods have been implemented in DRAM. For example, DRAM may operate in a power-down mode in which an internal circuit may be disabled when internal circuit elements are not in use. In the power-down mode, some elements in the DRAM may continue to consume power due to standby or leakage currents of the transistor(s). A power gating switch may be used as a way to reduce standby power consumption. The power gating switch may be located between a power source and one or more downstream logic elements and may supply power to the downstream logic elements when turned on and cut off power supply when turned off.

### SUMMARY

The inventive concept provides a memory device in which a power gating switch may be located in a cell array structure in which a plurality of memory cells including vertical channel transistors are implemented.

According to an aspect of the inventive concept, a memory device includes a core peripheral circuit structure including an internal power supply voltage line and a first bonding metal pad connected to the internal power supply voltage line and a cell array structure disposed on the core peripheral circuit structure and including an external power supply voltage line for conducting an external power supply voltage applied from outside of the memory device and a second bonding metal pad in contact with the first bonding metal pad, wherein the cell array structure includes a memory cell array and a power gating switch connected between the external power supply voltage line and the first bonding metal pad, wherein the power gating switch is located in a region of the cell array structure different from the memory cell array, and the power gating switch is configured to selectively provide the external power supply voltage to the internal power supply voltage line.

According to another aspect of the inventive concept, a memory device includes a core peripheral circuit structure including an internal ground voltage line and a first bonding metal pad connected to the internal ground voltage line and a cell array structure disposed on the core peripheral circuit structure and including an external ground voltage line for conducting an external ground voltage applied from outside of the memory device and a second bonding metal pad in contact with the first bonding metal pad, wherein the cell array structure includes a memory cell array and a power gating switch connected between the external ground voltage line and the first bonding metal pad, wherein the power gating switch is located in a region of the cell array structure different from the memory cell array, and the power gating switch is configured to selectively provide the external ground voltage to the internal ground voltage line.

According to another aspect of the inventive concept, a memory device includes a core peripheral circuit structure including an internal power supply voltage line, an internal ground voltage line, a first bonding metal pad connected to the internal power supply voltage line, and a second bonding metal pad connected to the internal ground voltage line and a cell array structure overlapping the core peripheral circuit structure in a vertical direction and including an external power supply voltage line for conducting an external power supply voltage applied from outside of the memory device, an external ground voltage line for conducting an external ground voltage applied from the outside of the memory device, a third bonding metal pad in contact with the first bonding metal pad, and a fourth bonding metal pad in contact with the second bonding metal pad, wherein the cell array structure includes a memory cell array including a plurality of memory cells and a power gating switch located in a region of the cell array structure different from the memory cell array, the power gating switch includes a first power gating circuit connected between the external power supply voltage line and the third bonding metal pad and a second power gating circuit connected between the external ground voltage line and the fourth bonding metal pad, and the first power gating circuit is configured to selectively provide the external power supply voltage to the internal power supply voltage line, and the second power gating circuit is configured to selectively provide the external ground voltage to the internal ground voltage line.

### BRIEF DESCRIPTION OF THE DRAWINGS

Embodiments will be more clearly understood from the following detailed description taken in conjunction with the accompanying drawings in which:

FIG. 1 is a diagram conceptually illustrating a memory device according to embodiments;

FIG. 2 shows a configuration of the memory device of FIG. 1;

FIG. 3, FIG. 4, FIG. 5, and FIG. 6 are diagrams illustrating a structure of a memory device according to embodiments;

FIG. 7, FIG. 8, FIG. 9A, and FIG. 9B are diagrams illustrating a power gating switch according to embodiments; and

FIG. 10 is a block diagram of a system for explaining an electronic device including a memory device according to embodiments.

### DETAILED DESCRIPTION

Hereinafter, embodiments of the inventive concept will be described in detail with reference to the attached drawings. The same reference numerals are used for the same components in the drawings, and redundant descriptions thereof may be omitted.

The present disclosure allows for various changes and numerous embodiments, specific embodiments will be illustrated in the drawings and described in detail in the written description. However, this is not intended to limit embodiments to particular modes of practice, and it is to be appreciated that all changes, equivalents, and substitutes that do not depart from the spirit and technical scope of the inventive concept are encompassed by the present disclosure. In the present disclosure, certain detailed descriptions may be omitted when they serve to obscure the essence of the inventive concept.

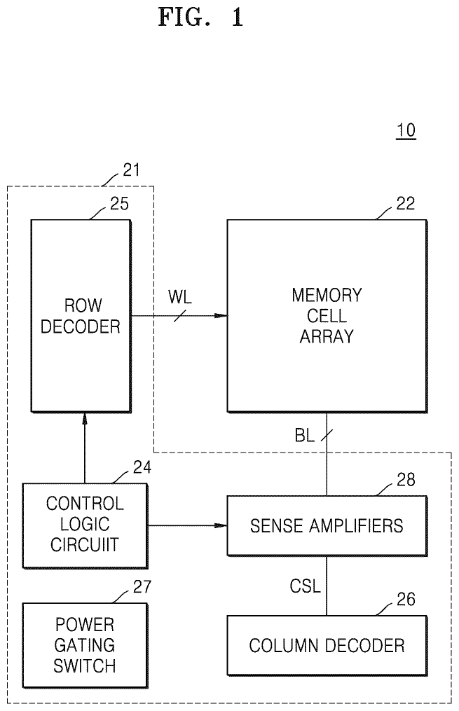

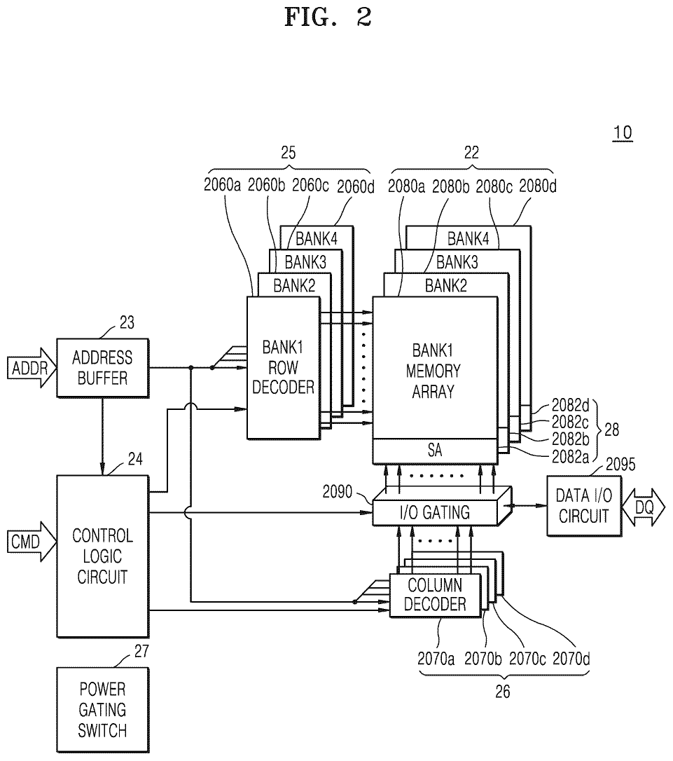

FIG. 1 is a diagram conceptually illustrating a memory device 10 according to some embodiments. FIG. 2 shows an example configuration of the memory device 10 of FIG. 1.

Referring to FIG. 1 and FIG. 2, the memory device 10 may include a core peripheral circuit 21 and a memory cell array 22. The core peripheral circuit 21 may include a control logic circuit 24, a row decoder 25, a column decoder 26, a power gating switch 27, and a sense amplifier 28. The core peripheral circuit 21 may further include an address buffer 23, an input/output (I/O) gating circuit 2090, a data I/O circuit 2095, etc. In some embodiments, the memory device 10 may be dynamic random access memory (DRAM) including a plurality of memory cells having a vertical channel transistor and a capacitor. Hereinafter, a “memory device” may be referred to as DRAM.

The memory cell array 22 may be connected to the row decoder 25. The memory cell array 22 may be connected to the row decoder 25 through word lines WL. The memory cell array 22 may be connected to the sense amplifier 28 through bit lines BL. The memory cell array 22 may include a first bank memory array 2080a, a second bank memory array 2080b, a third bank memory array 2080c, and a fourth bank memory array 2080d. Each of the first to fourth bank memory arrays 2080a, 2080b, 2080c, and 2080d may include a plurality of word lines WL, a plurality of bit lines BL, and a plurality of memory cells. The plurality of memory cells may be formed at intersections of the word lines WL and the bit lines BL.

The row decoder 25 may include a first bank row decoder 2060a, a second bank row decoder 2060b, a third bank row decoder 2060cm, and a fourth bank row decoder 2060d respectively connected to first to fourth bank memory arrays 2080a, 2080b, 2080c, and 2080d. The column decoder 26 may include a first bank column decoder 2070a, a second bank column decoder 2070b, a third bank column decoder 2070c, and a fourth bank column decoder 2070d respectively connected to the first to fourth bank memory arrays 2080a, 2080b, 2080c, and 2080d. The sense amplifier 28 may include a first sense amplifier 2082a, a second sense amplifier 2082b, a third sense amplifier 2082c, and a fourth sense amplifier 2082d respectively connected to the first to fourth bank memory arrays 2080a, 2080b, 2080c, and 2080d.

The first to fourth bank memory arrays 2080a, 2080b, 2080c, and 2080d, first to fourth bank row decoders 2060a, 2060b, 2060c, and 2060d, first to fourth bank column decoders 2070a, 2070b, 2070c, and 2070d, and first to fourth sense amplifiers 2082a, 2082b, 2082c, and 2082d may configure a first bank BANK1, a second bank BANK2, a third bank BANK3, and a fourth bank BANK4, respectively. The first to fourth bank row decoders 2060a, 2060b, 2060c, and 2060d, first to fourth bank column decoders 2070a, 2070b, 2070c, and 2070d, and first to fourth sense amplifiers 2082a, 2082b, 2082c, and 2082d may be referred to as core circuits of the first to fourth banks BANK1 to BANK4. In an embodiment, although an example of the memory device 10 including four banks is shown, the present disclosure is not limited thereto and the memory device 10 may include other numbers of banks according to some embodiments.

The address buffer 23 may receive an address ADDR including a row address and a column address. The address buffer 23 may receive the address ADDR from a memory controller connected to the memory device 10. In addition, the address ADDR may include a bank address. The address buffer 23 may provide the received bank address to a bank control logic, provide the received row address to the row decoder 25, and provide the received column address to the column decoder 26. The bank control logic may generate bank control signals in response to the bank address. In response to the bank control signals, a bank row decoder corresponding to the bank address among the first to fourth bank row decoders 2060a, 2060b, 2060c, and 2060d maybe activated, and a bank column decoder corresponding to the bank address among the first to fourth bank column decoders 2070a, 2070b, 2070c, and 2070d may be activated.

The control logic circuit 24 may control one or more operations of the memory device 10. The control logic circuit 24 may generate control signals to perform a write operation and/or a read operation of the memory device 10. The control logic circuit 24 may include a mode register, which may set a plurality of operation options of the memory device 10, and a command decoder, which may decode a command CMD received from the memory controller.

The sense amplifier 28 may sense data stored in a memory cell. The sense amplifier 28 may transmit the sensed data to the data I/O circuit 2095 to output the sensed data to the memory controller through data pad(s). The data I/O circuit 2095 may receive data to be written in memory cells from the memory controller through data pad(s). The data I/O circuit 2095 may transfer the received data to the memory cell array 22. The I/O gating circuit 2090 may output read data using a data line amplifier that receives and amplifies data sensed by the sense amplifier 28. The read data may be output to the memory controller through data pad(s). The I/O gating circuit 2090 may include circuits for gating I/O data DQ, a column selection circuit, an input data mask logic, read data latches for storing read data output from the first to fourth bank memory arrays 2080a, 2080b, 2080c, and 2080d, and a write driver for writing data to the first to fourth bank memory arrays 2080a, 2080b, 2080c, and 2080d.

Read data output from a bank memory array among the first to fourth bank memory arrays 2080a, 2080b, 2080c, and 2080d may be sensed by the sense amplifiers 2082a, 2082b, 2082c, and 2082d corresponding to the bank memory array and stored in the read data latches. Write data to be written to the memory cell array of a bank memory array among of the first to fourth bank memory arrays 2080a, 2080b, 2080c, and 2080d may be provided from the memory controller to the data I/O circuit 2095. The data provided to the data I/O circuit 2095 may be written to the bank memory array through a write driver.

The memory device 10 may include one or more power gating switches 27. The power gating switches 27 may selectively supply power to the core peripheral circuit 21. The power gating switch 27 may selectively supply power to each of the control logic circuit 24, the row decoder 25, the column decoder 26, the sense amplifier 28, the address buffer 23, the I/O gating circuit 2090, and the data I/O circuit 2095 included in the core peripheral circuit 21.

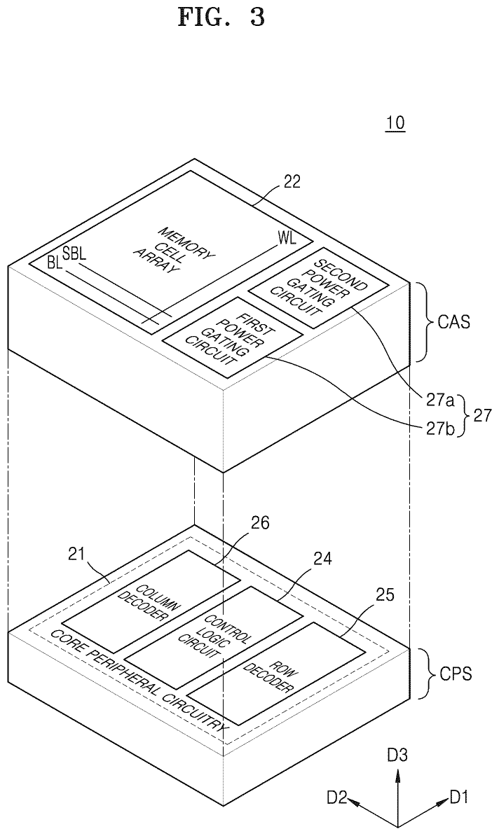

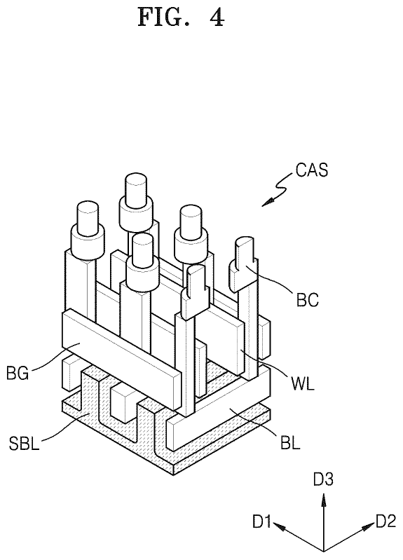

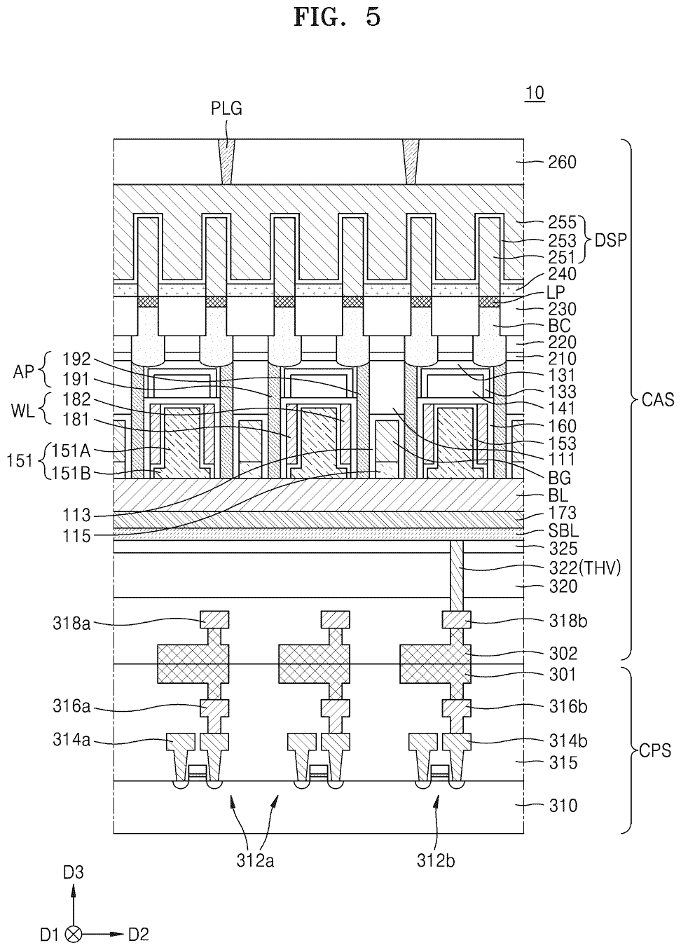

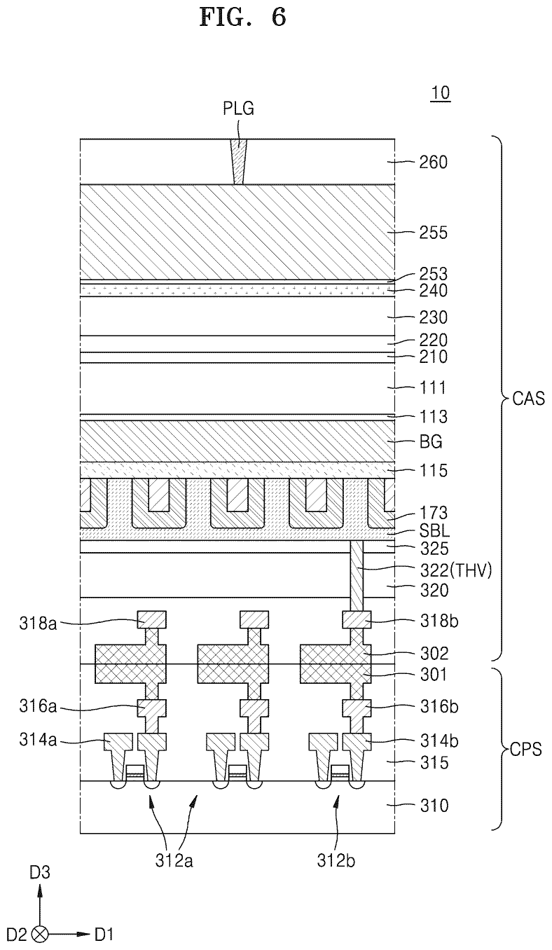

The power gating switch 27 may include a power supply network PDN that is configured to supply power to the core peripheral circuit 21. In a case that the power gating switch 27 is included in the same plane as the core peripheral circuit 21, such as in the core peripheral circuit structure CPS (FIG. 3), the chip size of the memory device 10 may increase due to the area of the power gating switch(es) 27 located in the core peripheral circuit structure CPS. In this case, the number of power gating switch(es) 27 located in the core peripheral circuit structure CPS may be reduced due to limitations in memory chip size. A reduction in the number of power gating switch(es) 27 may cause the power supply network PDN for the core peripheral circuit 21 to be limited. In addition, the chip size of the memory device 10 may increase due to the area of the power gating switch(es) 27 located in the core peripheral circuit structure CPS. With the power gating switch(es) 27 placed in an empty region of a cell array structure CAS (FIG. 3), the area of the power gating switch(es) 27 occupied in the core peripheral circuit structure CPS may be reduced, and the chip size of the memory device 10 may be reduced. In addition, the power supply network PDN associated with the core peripheral circuit 21 may be improved when the power gating switch(es) 27 are located in the empty space(s) of the cell array structure CAS, which may improve an operating performance of the memory device 10.

FIG. 3, FIG. 4, FIG. 5, and FIG. 6 are diagrams illustrating the structure of the memory device 10 according to some embodiments. In the drawings a first direction D1 and a second direction D2 intersect and form a horizontal plane, and a third direction D3 intersect the horizontal plane in a vertical direction. FIG. 4 is a perspective view illustrating the cell array structure CAS of the memory device 10 of FIG. 3. FIG. 5 is a cross-sectional view of the memory device 10 of FIG. 4 taken along a position corresponding to a second direction D2 in the perspective view. FIG. 6 is a cross-sectional view of the memory device 10 of FIG. 4 illustrating a cut surface cut along a position corresponding to the first direction D1. For convenience of understanding, those described as upper surface/lower surface, top/bottom, upper/lower, etc. may be referred to based on the directions shown in the reference drawings. Accordingly, the same surfaces may be referred to as an upper surface and a lower surface, respectively, according to the directions shown in the drawings.

Referring to FIG. 2 and FIG. 3, the memory device 10 may include the cell array structure CAS and the core peripheral circuit structure CPS that overlap each other in a third direction D3. That is, the cell array structure CAS may be disposed on the core peripheral circuit structure CPS. The cell array structure CAS may include the memory cell array 22 and the power gating switch 27. The power gating switch 27 may include a first power gating circuit 27a and a second power gating circuit 27b. The core peripheral circuit structure CPS may include the core peripheral circuit 21 including the address buffer 23, the control logic circuit 24, the row decoder 25, the column decoder 26, the sense amplifier 28, the I/O gating circuit 2090, and the data I/O circuit 2095. For the sake of brevity of the drawings, the circuits forming the control logic circuit 24, the row decoder 25, and the column decoder 26 are shown as being arranged in the core peripheral circuit structure CPS. The memory device 10 may have a structure in which the memory cell array 22 is disposed above the core peripheral circuit, that is, a cell over periphery (COP) structure.

In the memory cell array 22 of the cell array structure CAS, the word lines WL may extend in the first direction D1 and bit lines BL may extend in the second direction D2. Shielding bit lines SBL may be arranged adjacent to the bit lines BL. The memory cells including vertical channel transistors may be arranged at points at which the word lines WL and the bit lines BL intersect with each other.

The power gating switch 27 of the cell array structure CAS may include the first power gating circuit 27a and the second power gating circuit 27b. In an embodiment, the power gating switch 27 region is shown to be separated from the memory cell array 22 region. The power gating switch 27 may be placed in an empty region in which the memory cell array 22 is absent in the cell array structure CAS. With the power gating switch 27 placed in the cell array structure CAS and apart from the memory cell array 22, there may be no need to set up a separate region in the cell array structure CAS for accommodating the power gating switch 27.

In some embodiments, the first power gating circuit 27a may include at least one first transistor connected between an external power supply voltage VDD line (FIG. 8) and an internal power supply voltage VPWR line. An external power supply voltage VDD applied from outside the memory device 10 may be provided to the external power supply voltage VDD line. The first transistor of the first power gating circuit 27a may be configured as a P-type metal oxide semiconductor (PMOS) transistor. When the first transistor is turned on, the external power supply voltage VDD may be supplied to the internal power supply voltage VPWR line, and when the first transistor is turned off, the power supply voltage may be cut off. Accordingly, the external power supply voltage VDD may be selectively supplied to the internal power supply voltage VPWR line by turning on or off the first transistor, and the first transistor may be referred to as a switching transistor.

In some embodiments, the second power gating circuit 27b may include at least one second transistor connected between an external ground voltage VSS line (FIG. 8) and an internal ground voltage VGND line. An external ground voltage VSS applied from outside the memory device 10 may be provided to the external ground voltage VSS line. The second transistor may be configured as an N-type metal oxide semiconductor (NMOS) transistor. When the second transistor is turned on, the external ground voltage VSS may be supplied to the internal ground voltage VGND line, and when the second transistor is turned off, the ground voltage supply may be cut off. Accordingly, the external ground voltage VSS may be selectively supplied to the internal ground voltage VGND line by turning on or off the second transistor, and the second transistor may be referred to as a switching transistor.

In some embodiments, the external power supply voltage VDD and the external ground voltage VSS may be power sources provided to the memory device 10 from outside the memory device 10, and the internal power supply voltage VPWR and the internal ground voltage VGND may be power sources of the core peripheral circuit 21 of the memory device 10 (e.g., FIG. 8). In this case, the core peripheral circuit 21 may refer to downstream logic elements.

The core peripheral circuit structure CPS may include a semiconductor substrate, and the core peripheral circuit 21 may be formed by forming semiconductor elements, such as transistors, and patterns for interconnecting the elements on the semiconductor substrate. After the core peripheral circuit 21 is formed in the core peripheral circuit structure CPS, the cell array structure CAS including the memory cell array 22 may be formed, and patterns (e.g., bonding metal pads 301 and 302 of FIG. 5) may be formed to electrically connect the word lines WL, the bit lines BL, and the shielding bit lines SBL of the memory cell array 22 to the core peripheral circuit 21 formed in the core peripheral circuit structure CPS. However, the present disclosure is not limited thereto, and the cell array structure CAS may be formed before the core peripheral circuit structure CPS, or the core peripheral circuit structure CPS and the cell array structure CA may be formed simultaneously and bonded together. In addition, patterns (e.g., the bonding metal pads 301 and 302 in FIG. 5) for electrically connecting the power gating switch 27, the internal power supply voltage line(s) VPWR, and the internal ground voltage VGND line(s) to each other may be formed.

Referring to FIG. 4, FIG. 5, and FIG. 6 together, the core peripheral circuit structure CPS may include a lower substrate 310, an interlayer insulating film 315, a plurality of circuit elements 312a and 312b (or first circuit element 312a and second circuit element 312b), first metal layers 314a and 314b respectively connected to the circuit elements 312a and 312b, second metal layers 316a and 316b formed on the first metal layers 314a and 314b, and the bonding metal pad 301 formed on the uppermost metal layer of the core peripheral circuit structure CPS. In an embodiment, the first metal layers 314a and 314b may include tungsten having relatively high resistance, the second metal layers 316a and 316b may include copper having relatively low resistance, and the bonding metal pad 301 may include copper. In another embodiment, the bonding metal pad 301 may include aluminum (Al) or tungsten (W).

In this specification, the first metal layers 314a and 314b and the second metal layers 316a and 316b are shown and described, but the specification is not limited thereto, and at least one metal layer may be further formed on the second metal layers 316a and 316b. At least some of the one or more metal layers on top of the second metal layers 316a and 316b may include aluminum, etc., which has a lower resistance than copper forming the second metal layers 316a and 316b. The interlayer insulating film 315 may be disposed on the lower substrate 310 to cover the circuit elements 312a and 312b, the first metal layers 314a and 314b, and the second metal layers 316a and 316b. For example, the interlayer insulating film 315 may be encapsulate the circuit elements 312a and 312b, the first metal layers 314a and 314b, and the second metal layers 316a and 316b. The interlayer insulating film 315 may include insulating materials, such as silicon oxide, silicon nitride, etc.

The circuit elements 312a and 312b may be connected to at least one of the circuit elements forming the core peripheral circuit 21. For convenience of description, the first circuit element 312a represents transistors forming the row decoder 25, and the second circuit element 312b represents transistors forming the control logic circuit 24.

In the memory device 10, the bit lines BL may be arranged on an upper substrate 320 and may be disposed apart from each other in the first direction D1. The upper substrate 320 is expressed to indicate that the upper substrate 320 is an element corresponding to the lower substrate 310. According to some embodiments, the upper substrate 320 may be referred to as a plate or a conductive plate. The bit lines BL may be disposed apart from each other in the first direction D1 and extend in the second direction D2 intersecting with the first direction D1. Active patterns AP may be alternately arranged in the second direction D2 on each bit line BL. The active patterns AP may be disposed apart from each other at regular intervals in the first direction D1. That is, the active patterns AP may be two-dimensionally arranged in the first and second directions D1 and D2 intersecting with each other. In some embodiments, the word lines WL, the bit lines BL, and a plurality of active patterns AP may form a plurality of vertical channel transistors.

Each of the active patterns AP may have a length in the first direction D1, a width in the second direction D2, and a height in the third direction D3 perpendicular to the upper substrate 320. Each of the active patterns AP may have a substantially uniform width. Each of the active patterns AP may have an upper surface and a lower surface facing each other in the third direction D3. For example, the lower surface of the active patterns AP may contact the bit line BL. Each of the active patterns AP may include a source region adjacent to the bit line BL, a drain region adjacent to a contact pattern BC, and a channel region disposed between the source region and the drain region. The channel region of the active patterns AP may be controlled by the word lines WL and back gate electrodes BG during an operation of the memory device 10. The active patterns AP may include, for example, single crystal silicon (Si) that may improve leakage current characteristics during an operation of the memory device 10.

The back gate electrodes BG may be disposed apart from each other at a predetermined interval in the second direction D2 on the bit lines BL. The back gate electrodes BG may extend in the first direction D1 across the bit lines BL. Each of the back gate electrodes BG may be located between adjacent active patterns AP in the second direction D2. For example, the back gate electrodes BG may be located between a pair of active patterns AP in the second direction D2. A first active pattern 191 may be located on a first side of each of the back gate electrodes BG, and a second active pattern 192 may be located on a second side of each of the back gate electrodes BG. The back gate electrodes BG may have a height that is less than the height of the active patterns AP in the vertical direction. A negative voltage may be applied to the back gate electrodes BG during an operation of the memory device 10 and may increase a threshold voltage of the vertical channel transistor. As the vertical channel transistor becomes smaller, the threshold voltage decreases and a deterioration of the leakage current characteristics may be reduced or prevented.

A first insulating pattern 111 may be located between adjacent active patterns AP in the second direction D2. The first insulating pattern 111 may extend in the first direction D1 parallel to the back gate electrodes BG. A back gate insulating layer 113 may be located between each back gate electrode BG and each active pattern AP, and between the back gate electrode BG and the first insulating pattern 111. The back gate insulating layer 113 may include vertical portions covering sides of the back gate electrode BG and a horizontal portion connecting the vertical portions to each other. The horizontal portion of the back gate insulating layer 113 may be closer to the contact pattern BC than the bit line BL and may cover a lower surface of the back gate electrode BG. A back gate capping pattern 115 may be located between the bit lines BL and the back gate electrode BG. The back gate capping pattern 115 may include an insulating material, and the lower surface of the back gate capping pattern 115 may be in contact with the bit lines BL. The back gate capping pattern 115 may be located between the vertical portions of the back gate insulating layer 113.

The word lines WL may extend in the first direction D1 on the bit lines BL and may be alternately arranged in the second direction D2. The first word line 181 of the word lines WL may be disposed on a first side of the first active pattern 191, and the second word line 182 of the word lines WL may be disposed on a second side of the second active pattern 192. For example, a pair of word lines WL may be disposed outside a pair of active patterns including the first active pattern 191 and the second active pattern 192. Portions of the first word lines 181 may be located between first active patterns 191 adjacent in the first direction D1, and portions of the second word lines 182 may be located between the second active patterns 192 adjacent in the first direction D1.

The word lines WL may be vertically disposed apart from the bit lines BL and the contact patterns BC. The word lines WL may be located between the bit lines BL and the contact patterns BC from a vertical perspective. Adjacent word lines WL may have sidewalls facing each other. The word lines WL may have a height less than the height of the active patterns AP in the vertical direction. The height of the word lines WL may be equal to or greater than the height of the back gate electrodes BG in the third direction D3.

Gate insulating films 160 may be located between the word lines WL and the active patterns AP. The gate insulating films 160 may extend in the first direction D1 and may be substantially parallel to the word lines WL. The gate insulating film 160 may cover one surface of the first active pattern 191 and the other surface of the second active pattern 192. The gate insulating film 160 may have a substantially uniform thickness. The second insulating pattern 141 may be located between the gate insulating film 160 and the contact patterns BC. For example, the second insulating pattern 141 may include silicon oxide. A first etch stop layer 131 and a second etch stop layer 133 may be located between the active patterns AP and the second insulating pattern 141.

On the gate insulating film 160, the word lines WL may be separated from each other by the third insulating pattern 151. The third insulating pattern 151 may extend in the first direction D1 between the word lines WL. A first capping film 153 may be located between the third insulating pattern 151 and the word lines WL. The first capping film 153 may have a substantially uniform thickness. The third insulating pattern 151 may include a third vertical pattern 151A and a third horizontal pattern 151B.

The contact patterns BC may pass through the third etch stop layer 210 and the interlayer insulating film 220 and be respectively connected to the active patterns AP. In other words, the contact patterns BC may be respectively connected to drain regions of the active patterns AP. The contact patterns BC may have a lower width greater than an upper width of the contact patterns BC. Adjacent contact patterns BC may be separated from each other by separation insulating patterns 230. Each of the contact patterns BC may have various shapes, such as a circle, oval, rectangle, square, diamond, or hexagon in a plan view. Landing pads LP may be disposed on the contact patterns BC, respectively.

The separation insulating patterns 230 may be located between the landing pads LP. The landing pads LP may be arranged in a matrix form in the first direction D1 and the second direction D2 in a plan view. Upper surfaces of the landing pads LP may be substantially coplanar with upper surfaces of the separation insulating patterns 230. A fourth etch stop layer 240 may be formed on the separation insulating patterns 230.

Data storage patterns DSP may be disposed on the landing pads LP. The data storage patterns DSP may be respectively and electrically connected to the active patterns AP. The data storage patterns DSP may be arranged in a matrix form in the first direction D1 and the second direction D2. The data storage patterns DSP may completely or partially overlap the landing pads LP. The data storage patterns DSP may contact all or part of the upper surfaces of the landing pads LP. An upper insulating layer 260 may be disposed on the data storage patterns DSP, and cell contact plugs PLG may pass through the upper insulating layer 260 and be connected to the plate electrode 255.

In some embodiments, the data storage patterns DSP may be a capacitor and may include a capacitor dielectric film 253 located between the storage electrodes 251 and the plate electrode 255. In this case, the storage electrode 251 may be in direct contact with the landing pad LP and may have various shapes, such as a circle, oval, rectangle, square, diamond, or hexagon in a plan view.

In some embodiments, the data storage patterns DSP may be variable resistance patterns that may be switched between two resistance states by an electrical pulse applied to a memory element. For example, data storage patterns DSP may include phase-change materials, perovskite compounds, transition metal oxides, magnetic materials, ferromagnetic materials, antiferromagnetic materials, etc., of which the crystal state changes depending on the amount of current, but are not limited thereto. Depending on a material film of the data storage patterns DSP, the memory device 10 may be implemented as a resistive memory, such as phase change random access memory (PRAM), magnetic RAM (MRAM), or resistive RAM (RRAM).

A shielding bit line SBL may be located between the bit lines BL and below the bit lines BL. The shielding bit line SBL may reduce coupling noise between adjacent bit lines BL. For example, the shielding bit line SBL may be a shielding structure including a conductive material. First line insulating layers 173 may be disposed apart from each other in the first direction D1 and extend in the second direction D2. The first line insulating layers 173 may be formed to contact opposite sidewalls of neighboring bit lines BL and be separated from each other in the first direction D1. The second line insulating layer 325 may be formed to surround bottom and side surfaces of the shielding bit line SBL and fill a space between the shielding bit line(s) SBL.

A through-electrode 322 may pass through the upper substrate 320 to contact the metal layer 318b and extend in the third direction (the D3 direction) to reach the bonding metal pad 302 formed on the uppermost metal layer of the core peripheral circuit structure CPS. In an embodiment, only one of the metal layers 318a and 318b is shown and described, but without being limited thereto, and at least one metal layer may be further formed on the metal layer 318a and 318b. The shielding bit line SBL may be electrically connected to the second circuit element 312b of the control logic circuit 24 through the bonding metal pad 302 of the cell array structure CAS and the bonding metal pad 301 of the core peripheral circuit structure CPS. The shielding bit line SBL may be controlled by the control logic circuit 24. When the control logic circuit 24 detects and amplifies data of a memory cell selected from the memory cell array 22, the control logic circuit 24 may selectively provide a certain voltage, for example, a bit line precharge voltage, power supply voltage, or ground voltage, to the shielding bit line SBL to cause the shielding bit line SBL to be in a floating state.

In some embodiments, the bonding metal pad 302 of the cell array structure CAS and the bonding metal pad 301 of the core peripheral circuit structure CPS may be electrically and/or physically connected to each other through a bonding method. When the bonding metal pads 301 and 302 include copper (Cu), the bonding method may be a Cu—Cu bonding method. As another example, the bonding metal pads 301 and 302 may include aluminum (Al) or tungsten (W).

The metal layer 318a of the cell array structure CAS may be electrically and/or physically connected to each of the word lines WL and may be in contact with the bonding metal pad 302. Each of the word lines WL may be electrically connected to the first circuit element 312a of the row decoder 25 through the bonding metal pad 302 of the cell array structure CAS and the bonding metal pad 301 of the core peripheral circuit structure CPS. Hereinafter, the components and operations of the power gating switch 27 located in the cell array structure CAS are described in detail through various embodiments.

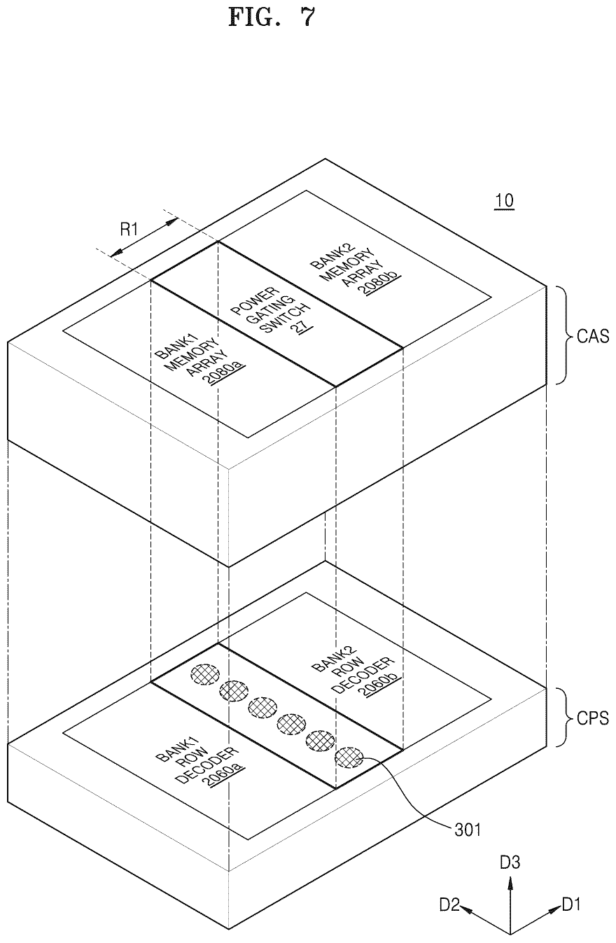

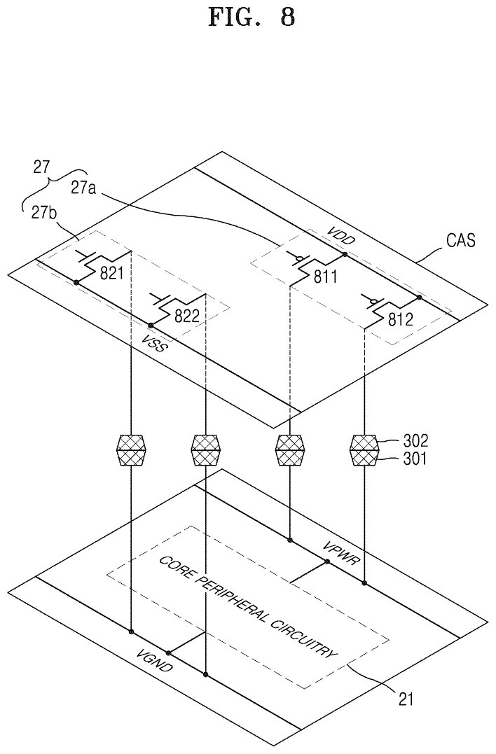

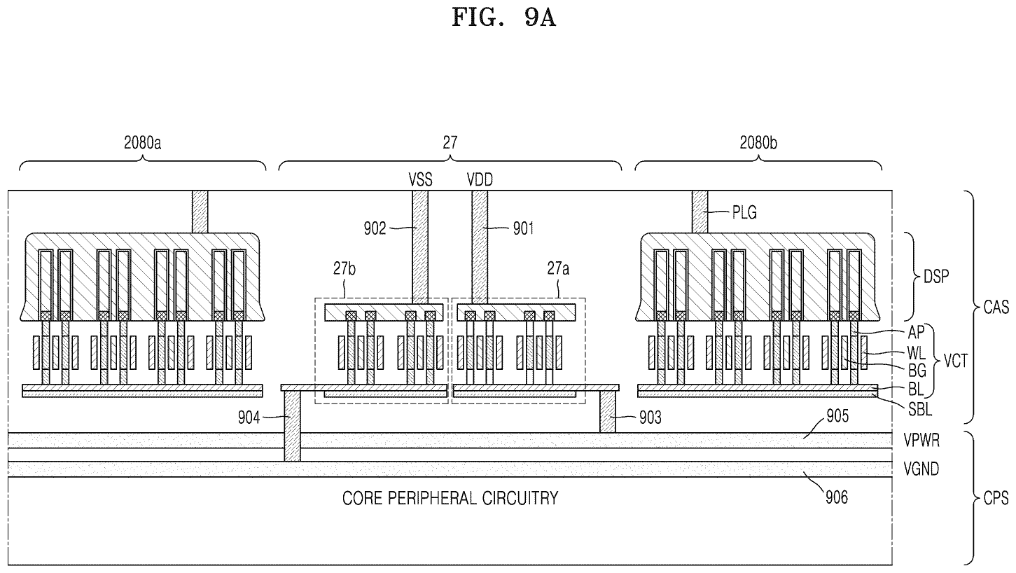

FIG. 7, FIG. 8, FIG. 9A, and FIG. 9B are diagrams illustrating the power gating switch 27 according to some embodiments. FIG. 7 and FIG. 8 are diagrams illustrating architecture of the power gating switch 27 located in the memory device 10. FIG. 9A and FIG. 9B show the power gating switch 27 implemented in the cell array structure CAS. For clarity of drawing, FIG. 7 shows a first bank BANK1 and a second bank BANK2 in FIG. 2.

Referring to FIG. 7 in conjunction with FIG. 2 and FIG. 3, the memory device 10 may include the cell array structure CAS and the core peripheral circuit structure PCS that overlap each other in the third direction (the D3 direction). The cell array structure CAS may include a first bank memory array 2080a region, a second bank memory array 2080b region, and the power gating switch 27 region. The power gating switch 27 region may be located between the first bank memory array 2080a region and the second bank memory array 2080b region.

In some embodiments, the memory cell array 22 in the cell array structure CAS may be divided into first to fourth bank memory arrays 2080a, 2080b, 2080c, and 2080d, and the first to fourth bank memory arrays 2080a, 2080b, 2080c, and 2080d may be arranged to be disposed apart from each other at a predetermined interval. A separation region R1 of the first to fourth bank memory arrays 2080a, 2080b, 2080c, and 2080d may be different from a memory cell region. For example, the separation region R1 may be adjacent to a memory cell region, disposed apart from a memory cell region, etc. The separation region R1 may omit vertical channel transistor structures and capacitor structures respectively connected to the vertical channel transistor structures. This means the separation region R1 may be an empty region of the cell array structure CAS. The power gating switch 27 may be disposed in the empty region of the cell array structure CAS different from a memory cell region.

In an embodiment, an example in which the power gating switch 27 region is located between the first bank memory array 2080a region and the second bank memory array 2080b region is described, but this is only an example to aid understanding and not intended to limit the inventive concept. In other embodiments, the power gating switch 27 region may be disposed in any empty region of the cell array structure CAS. For example, the power gating switch 27 region may be disposed in an region of the cell array structure CAS different from a region of a memory cell array.

In the core peripheral circuit structure CPS, first and second bank row decoder 2060a and 2060b regions respectively corresponding to the first and second bank memory arrays 2080a and 2080b may be apart from each other. The areas of the first and second bank row decoder 2060a and 2060b regions may partially overlap the first and second bank memory array 2080a and 2080b regions from a vertical perspective. A plurality of bonding metal pads 301 connected to the power gating switch 27 of the cell array structure CAS may be included between the first and second bank row decoder 2060a and 2060b regions.

In an embodiment, the row decoder 25 including the first and second bank row decoders 2060a and 2060b may be described as being located in the core peripheral circuit structure CPS, but is not limited thereto, and a certain circuit of the core peripheral circuit 21 may be included. For example, instead of the row decoder 25, the control logic circuit 24, the column decoder 26, the sense amplifier 28, the address buffer 23, the I/O gating circuit 2090, or the data I/O circuit 2095 may be located in the core peripheral circuit structure CPS.

Referring to FIG. 7 and FIG. 8, the power gating switch 27 of the cell array structure CAS may include a first power gating circuit 27a and a second power gating circuit 27b. The first power gating circuit 27a may include a plurality of PMOS transistors 811 and 812 electrically connected between the external power supply voltage VDD line of the cell array structure CAS and the internal power supply voltage VPWR line of the core peripheral circuit structure CPS. The plurality of PMOS transistors 811 and 812 may be connected in parallel between the external power supply voltage VDD line of the cell array structure CAS and the internal power supply voltage VPWR line. Each of the PMOS transistors 811 and 812 may be connected between the external power supply voltage VDD line and the bonding metal pad 302 of the cell array structure CAS, and the bonding metal pad 302 of the cell array structure CAS may be in contact with the bonding metal pad 301 connected to the internal power supply voltage VPWR line of the core peripheral circuit structure CPS.

The second power gating circuit 27b may include a plurality of NMOS transistors 821 and 822 electrically connected between the external ground voltage VSS line of the cell array structure CAS and the internal ground voltage VGND line of the core peripheral circuit structure CPS. The plurality of NMOS transistors 821 and 822 may be connected in parallel between the external ground voltage VSS line and the internal ground voltage VGND line. The NMOS transistors 821 and 822 may be connected between the external ground voltage VSS line and the bonding metal pad 302 of the cell array structure CAS, and the bonding metal pad 302 of the cell array structure CAS may be in contact with the bonding metal pad 301 connected to the internal ground voltage VGND line of the peripheral circuit structure CPS.

In some embodiments, the PMOS transistors 811 and 812 of the first power gating circuit 27a and the NMOS transistors 821 and 822 of the second power gating circuit 27b may be controlled by the control logic circuit 24. The control logic circuit 24 may be configured to control the PMOS transistors 811 and 812 to be turned on so that the external power supply voltage VDD may be supplied to the internal power supply voltage VPWR line. The control logic circuit 24 may be configured to control the PMOS transistors 811 and 812 to be turned off and supply of the external power supply voltage VDD to the internal power supply voltage VPWR line may be cut off. The control logic circuit 24 may be configured to supply the external ground voltage VSS to the internal ground voltage VGND line when the NMOS transistors 821 and 822 are turned on and configured to cut off supply of the external ground voltage VSS to the internal ground voltage VGND line when the NMOS transistors 821 and 822 are turned off. The PMOS transistors 811 and 812 of the first power gating circuit 27a and the NMOS transistors 821 and 822 of the second power gating circuit 27b may function as switching transistors.

Referring to FIG. 9A in conjunction with FIG. 5, FIG. 7, and FIG. 8, memory cells including the data storage pattern DSP, the word line WL, a back gate electrode BG, the active pattern AP, the bit line BL, and the shielding bit line SBL may be arranged in each of the first and second bank memory array 2080a and 2080b regions of the cell array structure CAS. The word line WL, back active pattern AP, and bit line BL may form a vertical channel transistor VCT. The active pattern AP of the vertical channel transistor VCT in the first and second bank memory arrays 2080a and 2080b may include a first type of conductive material, for example, an N-type conductive material.

In the power gating switch 27 region of the cell array structure CAS, the first and second power gating circuits 27a and 27b may be connected to the external power supply voltage VDD line and the external ground voltage VSS line through I/O contact plugs 901 and 902. The PMOS transistors 811 and 812 and the NMOS transistors 821 and 822 of the respective first and second power gating circuits 27a and 27b may be formed in the process of forming the vertical channel transistor VCT of the first and second bank memory arrays 2080a and 2080b. That is, the PMOS transistors 811 and 812 and the NMOS transistors 821 and 822 of the first and second power gating circuits 27a and 27b may be formed having a same structure as that of the vertical channel transistor VCT. Accordingly, the PMOS transistors 811 and 812 and the NMOS transistors 821 and 822 may be implemented having the same patterns as the vertical channel transistor VCT. The PMOS transistors 811 and 812 and the NMOS transistors 821 and 822 of the first and second power gating circuits 27a and 27b may be implemented in a configuration in which a plurality of vertical channel transistors VCT are connected in parallel. That is, the PMOS transistors 811 and 812 may be connected in parallel between the external power supply voltage VDD line and the internal power supply voltage VPWR line, and the NMOS transistors 821 and 822 may be connected in parallel between the external ground voltage VSS line and the internal ground voltage VGND line.

In some embodiments, the transistors 811 and 812 of the first power gating circuit 27a may include a second type of conductive material, for example, a P-type conductive material, in the active pattern AP of the vertical channel transistor VCT. The transistors 821 and 822 of the second power gating circuit 27b may include a first type of conductive material, for example, an N-type conductive material, in the active pattern AP of the vertical channel transistor VCT. That is, the transistors 811 and 812 of the first power gating circuit 27a and the transistors 821 and 822 of the second power gating circuit 27b may have opposite conductivity types. Further, the transistors 821 and 822 of the second power gating circuit 27b may have a same conductivity type as the active pattern AP of the vertical channel transistor VCT in the first and second bank memory arrays 2080a and 2080b.

In the first power gating circuit 27a, the first I/O contact plug 901 to which the external power supply voltage VDD line is connected may be connected in parallel to the active patterns AP and the bit line BL of the transistors 811 and 812. The third I/O contact plug 903 connected to the bit line BL to which the transistors 811 and 812 are connected in parallel may be connected to an internal power supply voltage VPWR line 905 of the core peripheral circuit structure CPS. The word lines WL of the transistors 811 and 812 may also be connected in parallel and may be controlled by the control logic circuit 24 to turn the transistors 811 and 812 on or off.

In the second power gating circuit 27b, the second I/O contact plug 902 to which the external ground voltage VSS line is connected may be connected in parallel to the active patterns AP and the bit line BL of the transistors 821 and 822, and the fourth I/O contact plug 904 connected to the bit line BL to which the transistors 821 and 822 are connected in parallel may be connected to an internal ground voltage VGND line 906 of the core peripheral circuit structure CPS. The word lines WL of the transistors 821 and 822 may also be connected in parallel and may be controlled by the control logic circuit 24 to turn the transistors 821 and 822 on or off.

Referring to FIG. 9B in conjunction with FIG. 5, FIG. 7, and FIG. 8, in the cell array structure CAS, the first and second bank memory array 2080a and 2080b regions and power gating switch 27 regions may be disposed above the internal power supply voltage VPWR line 905 and the internal ground voltage VGND line 906. The first I/O contact plug 911 connected to the external power supply voltage VDD line 915 may be connected in parallel to the active patterns AP and the bit line BL of the transistors 811 and 812. The third I/O contact plug 913 connected to the bit line BL to which the transistors 811 and 812 are connected in parallel may be connected to the internal power supply voltage VPWR line 905 of the core peripheral circuit structure CPS. The second I/O contact plug 912 to which the external ground voltage VSS line 916 is connected may be connected in parallel to the active patterns AP and the bit line BL of the transistors 821 and 822, and the fourth I/O contact plug 914 connected to the bit line BL to which the transistors 821 and 822 are connected in parallel may be connected to the internal ground voltage VGND line 906 of the core peripheral circuit structure CPS.

In some embodiments, the PMOS transistors 811 and 812 and the NMOS transistors 821 and 822 of the first and second power gating circuits 27a and 27b may be implemented as fin field effect transistors (finFET). The finFET may include a gate structure extending in the second direction perpendicular to the first direction, while covering a portion of a fin-type active region extending in the first direction on the upper substrate 320 of the cell array structure CAS, and source and drain regions disposed at sides of the gate structure in the first direction.

In some embodiments, the PMOS transistors 811 and 812 and the NMOS transistors 821 and 822 of the first and second power gating circuits 27a and 27b may be implemented as planar field effect transistors. The planar field effect transistors may include a gate structure extending in the second direction on the upper substrate 320 of the cell array structure CAS and source and drain regions on sides of the gate structure in the first direction perpendicular to the second direction.

As described herein, the chip size of the memory device 10 may be reduced by placing power gating switches in empty spaces of the cell array structure. For example, the power gating switches may be disposed in a region of the cell array structure different from the memory cell array. In addition, by improving the power supply network PDN through power gating switches located in the cell array structure, the operating performance of the memory device 10 may be improved.

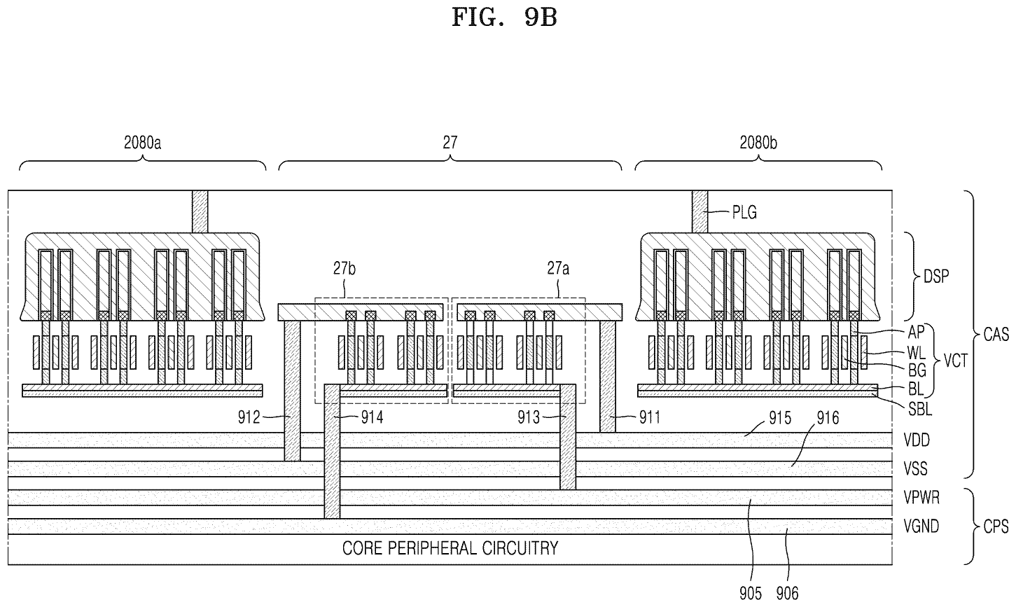

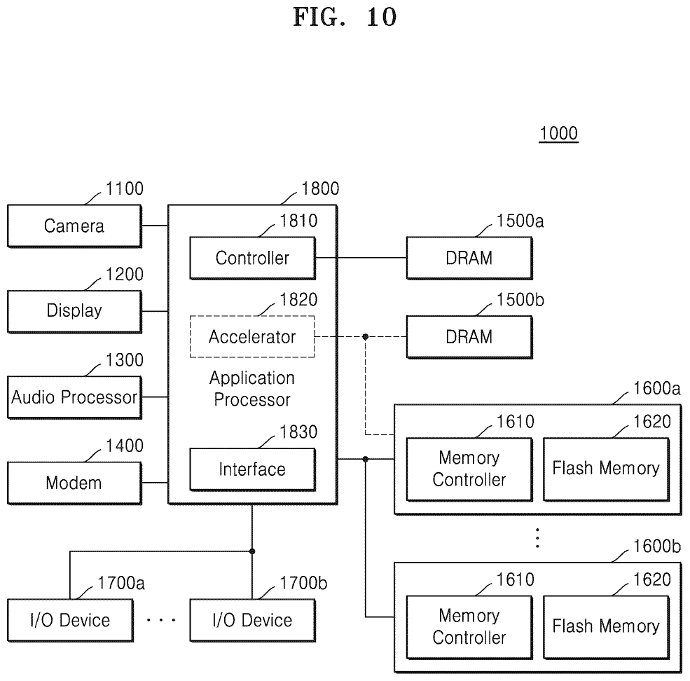

FIG. 10 is a block diagram of a system 1000 illustrating an electronic device including a memory device according to some embodiments.

Referring to FIG. 10, the system 1000 may include a camera 1100, a display 1200, an audio processor 1300, a modem 1400, DRAMs 1500a and 1500b, flash memories 1600a and 1600b, and I/O devices 1700a and 1700b, and an application processor (AP) 1800. The system 1000 may be implemented as a laptop computer, mobile phone, smartphone, tablet personal computer, wearable device, healthcare device, or Internet of things (IoT) device. In addition, the system 1000 may be implemented as a server or personal computer.

The camera 1100 may capture still images or moving images under user control, and store or transmit a captured image/video data to the display 1200. The audio processor 1300 may process audio data included in the flash memories 1600a and 1600b or network content. The modem 1400 may modulate and transmit signals for wired/wireless data transmission and reception and a receiving side may demodulate the transmitted signals to restore the original signals. The I/O devices 1700a and 1700b may include devices that provide digital input and/or output functions, such as a universal serial bus (USB) or storage, a digital camera, a secure digital (SD) card, a digital versatile disc (DVD), a network adapter, a touch screen, etc.

The AP 1800 may control the overall operation of the system 1000. The AP 1800 may include a control block 1810, an accelerator block or accelerator chip 1820, and an interface block 1830. The AP 1800 may control the display 1200 so that part of the content stored in the flash memories 1600a and 1600b may be displayed on the display 1200. When a user input is received through the I/O devices 1700a and 1700b, the AP 1800 may perform a control operation corresponding to the user input. The AP 1800 may include an accelerator block, which may be a dedicated circuit for artificial intelligence (AI) data calculation, or may include an accelerator chip 1820 separate from the AP 1800. The DRAM 1500b may be additionally mounted on the accelerator block or accelerator chip 1820. The accelerator, which may be a function block that specializes in performing specific functions of the AP 1800, may include a graphics processing unit (GPU) that may be a functional block specializing in graphics data processing, a neural processing unit (NPU) that may be a block specializing in AI calculation and inference, or a data processing unit (DPU) that may be a block specializing in data transmission.

The system 1000 may include a plurality of DRAMs 1500a and 1500b. The AP 1800 may control the DRAMs 1500a and 1500b through command and mode register (MRS) settings that meet the Joint Electron Device Engineering Council (JEDEC) standard, or may set an interface protocol to perform communication to use entity-specific functions, such as low voltage/high speed/reliability, and cyclic redundancy check (CRC)/error correction code (ECC) functions. For example, the AP 1800 may communicate with the DRAM 1500a through an interface that complies with JEDEC standards, such as LPDDR4 and LPDDR5, and the accelerator block or accelerator chip 1820 may perform communication by setting a new DRAM interface protocol to control the DRAM 1500b for accelerators having a higher bandwidth than the DRAM 1500a.

In FIG. 10, only DRAMs 1500a and 1500b are shown, but the inventive concept is not limited thereto, and any memory, such as PRAM or SRAM, MRAM, RRAM, FRAM, or hybrid RAM, etc. may be used if it satisfies the bandwidth, response speed, and voltage conditions of the AP 1800 or the accelerator chip 1820. The DRAMs 1500a and 1500b have relatively smaller latency and bandwidth than the I/O devices 1700a and 1700b or the flash memories 1600a and 1600b. The DRAMs 1500a and 1500b may be initialized when the system 1000 is powered on, the operating system and application data may be loaded to the DRAMs 1500a and 1500b so that the DRAMs 1500a and 1500b may be used as temporary storage locations or may be used as an execution space for a variety of software code.

In the DRAMs 1500a and 1500b, addition/subtraction/multiplication/division arithmetic operations, vector operations, address operations, or fast Fourier transform (FFT) operations may be performed. In addition, a function used for inference may be performed within the DRAMs 1500a and 1500b. Here, inference may be performed in a deep learning algorithm using an artificial neural network. Deep learning algorithms may include a training operation to train a model through a variety of data and an inference operation to recognize data with the trained model. As an example, an image captured by a user through the camera 1100 may be signal-processed and stored in the DRAM 1500b, and the accelerator block or accelerator chip 1820 may perform an AI data operation to recognize data using the data stored in the DRAM 1500b and the function used for inference.

The system 1000 may include a plurality of storages or a plurality of flash memories 1600a and 1600b. The plurality of flash memories 1600a and 1600b may have relatively larger capacities than the DRAMs 1500a and 1500b. The accelerator block or accelerator chip 1820 may perform a training operation and AI data operation using the flash memories 1600a and 1600b. In an embodiment, the flash memories 1600a and 1600b may include a memory controller 1610 and a flash memory device 1620 and may efficiently perform a training operation performed by the AP 1800 and/or the accelerator chip 1820 and an inference AI data operation by using a calculation device provided in the memory controller 1610. The flash memories 1600a and 1600b may store photos taken through the camera 1100 or store data transmitted over a data network. For example, the flash memories 1600a and 1600b may store augmented reality/virtual reality, high definition (HD), or ultra-high definition (UHD) content.

In the system 1000, the DRAMs 1500a and 1500b may be the memory device described herein with reference to FIGS. 1 to 9. The memory device may include a core peripheral circuit structure disposed on a semiconductor substrate and a cell array structure overlapping the core peripheral circuit structure in a vertical direction on the core peripheral circuit structure. The core peripheral circuit structure may include a core peripheral circuit, an internal power supply voltage line and an internal ground voltage line connected to the core peripheral circuit, a first bonding metal pad connected to the internal power supply voltage line, and a second bonding metal pad connected to the internal ground voltage line. The core peripheral circuit structure may exclude a memory cell array among components of the memory device. The cell array structure may include a memory cell array including a third bonding metal pad in contact with the first bonding metal pad, a fourth bonding metal pad in contact with the second bonding metal pad, a plurality of vertical channel transistor structures, and a plurality of capacitor structures respectively connected to the vertical channel transistor structures, an external power supply voltage line provided with an external power supply voltage applied from the outside of the memory device, an external ground voltage line provided with an external ground voltage applied from the outside of the memory device, and a power gating switch located in an empty region of the cell array structure. The power gating switch may selectively provide the external power supply voltage to the internal power supply voltage line using a first power gating circuit connected between the external power supply voltage line and the first bonding metal pad and selectively provide the external ground voltage to the internal ground voltage line using a second power gating circuit connected between the external ground voltage line and the second bonding metal pad. By locating the power gating switches in an empty space of the cell array structure, for example, a region excluding a memory cell array, the chip size of the memory device may be reduced and the power supply network PDN for the core peripheral circuit may be improved, which may improve an operating performance of the memory device.

While the inventive concept has been particularly shown and described with reference to embodiments thereof, it will be understood that various changes in form and details may be made therein without departing from the spirit and scope of the following claims.

What is claimed is:

1. A memory device comprising:
a core peripheral circuit structure including an internal power supply voltage line and a first bonding metal pad connected to the internal power supply voltage line; and
a cell array structure disposed on the core peripheral circuit structure and including an external power supply voltage line for conducting an external power supply voltage applied from outside of the memory device and a second bonding metal pad in contact with the first bonding metal pad,
wherein the cell array structure includes a memory cell array and a power gating switch connected between the external power supply voltage line and the first bonding metal pad, wherein the power gating switch is located in a region of the cell array structure different from the memory cell array, and
the power gating switch is configured to selectively provide the external power supply voltage to the internal power supply voltage line.

2. The memory device of claim 1, wherein the power gating switch includes a plurality of switching transistors electrically connected between the external power supply voltage line and the internal power supply voltage line.

3. The memory device of claim 2, wherein the plurality of switching transistors are connected in parallel between the external power supply voltage line and the internal power supply voltage line.

4. The memory device of claim 1, further comprising a plurality of vertical channel transistors,
each of the vertical channel transistors comprising:
a portion of an upper substrate;
a bit line disposed on the upper substrate and extending in a second direction intersecting with a first direction;
a pair of active patterns disposed on the bit line;
a back gate electrode located between the pair of active patterns and extending in the first direction; and
a pair of word lines disposed outside the pair of active patterns and extending in the first direction.

5. The memory device of claim 4, wherein the power gating switch includes a plurality of switching transistors electrically connected between the external power supply voltage line and the internal power supply voltage line, and
each switching transistor of the plurality of switching transistors has a same structure as the plurality of vertical channel transistors, and the pair of active patterns of the plurality of switching transistors and the pair of active patterns of the plurality of vertical channel transistors have opposite conductivity types.

6. The memory device of claim 1, wherein the memory cell array includes a shielding bit line located between a plurality of bit lines, including the bit line, and below the plurality of bit lines.

7. A memory device comprising:
a core peripheral circuit structure including an internal ground voltage line and a first bonding metal pad connected to the internal ground voltage line; and
a cell array structure disposed on the core peripheral circuit structure and including an external ground voltage line for conducting an external ground voltage applied from outside of the memory device and a second bonding metal pad in contact with the first bonding metal pad,
wherein the cell array structure includes a memory cell array and a power gating switch connected between the external ground voltage line and the first bonding metal pad, wherein the power gating switch is located in a region of the cell array structure different from the memory cell array, and
the power gating switch is configured to selectively provide the external ground voltage to the internal ground voltage line.

8. The memory device of claim 7, wherein the power gating switch includes a plurality of switching transistors electrically connected between the external ground voltage line and the internal ground voltage line.

9. The memory device of claim 8, wherein the plurality of switching transistors are connected in parallel between the external ground voltage line and the internal ground voltage line.

10. The memory device of claim 7, further comprising a plurality of vertical channel transistors,
each of the vertical channel transistors comprising:
a portion of an upper substrate;
a bit line disposed on the upper substrate and extending in a second direction intersecting with a first direction;
a pair of active patterns disposed on the bit line;
a back gate electrode located between the pair of active patterns and extending in the first direction; and
a pair of word lines disposed outside the pair of active patterns and extending in the first direction.

11. The memory device of claim 10, wherein the power gating switch includes a plurality of switching transistors electrically connected between the external ground voltage line and the internal ground voltage line, and
each switching transistor of the plurality of switching transistors has a same structure as the plurality of vertical channel transistors, and the pair of active patterns of the plurality of switching transistors and the pair of active patterns of the plurality of vertical channel transistors have a same conductivity type.

12. The memory device of claim 7, wherein the memory cell array includes a shielding bit line located between a plurality of bit lines, including the bit line, and below the plurality of bit lines.

13. A memory device comprising:
a core peripheral circuit structure including an internal power supply voltage line, an internal ground voltage line, a first bonding metal pad connected to the internal power supply voltage line, and a second bonding metal pad connected to the internal ground voltage line; and
a cell array structure overlapping the core peripheral circuit structure in a vertical direction and including an external power supply voltage line for conducting an external power supply voltage applied from outside of the memory device, an external ground voltage line for conducting an external ground voltage applied from the outside of the memory device, a third bonding metal pad in contact with the first bonding metal pad, and a fourth bonding metal pad in contact with the second bonding metal pad,
wherein the cell array structure includes a memory cell array including a plurality of memory cells and a power gating switch located in a region of the cell array structure different from the memory cell array,
the power gating switch includes a first power gating circuit connected between the external power supply voltage line and the third bonding metal pad and a second power gating circuit connected between the external ground voltage line and the fourth bonding metal pad, and
the first power gating circuit is configured to selectively provide the external power supply voltage to the internal power supply voltage line, and the second power gating circuit is configured to selectively provide the external ground voltage to the internal ground voltage line.

14. The memory device of claim 13, wherein
the first power gating circuit includes a plurality of first switching transistors electrically connected between the external power supply voltage line and the internal power supply voltage line, and
the second power gating circuit includes a plurality of second switching transistors electrically connected between the external ground voltage line and the internal ground voltage line.

15. The memory device of claim 14, wherein the first switching transistors include PMOS transistors.

16. The memory device of claim 14, wherein the second switching transistors include NMOS transistors.

17. The memory device of claim 14, wherein the plurality of first switching transistors are connected in parallel between the external power supply voltage line and the internal power supply voltage line and the plurality of second switching transistors are arranged connected in parallel between the external ground voltage line and the internal ground voltage line.

18. The memory device of claim 14, further comprising a plurality of vertical channel transistors,
each of the vertical channel transistors comprising:
a portion of an upper substrate;
a bit line disposed on the upper substrate and extending in a second direction intersecting with a first direction;
a pair of active patterns disposed on the bit line;
a back gate electrode located between the pair of active patterns and extending in the first direction; and
a pair of word lines disposed outside the pair of active patterns and extending in the first direction.

19. The memory device of claim 18, wherein the memory cell array includes a shielding bit line located between a plurality of bit lines, including the bit line, and below the plurality of bit lines.

20. The memory device of claim 13, wherein
the core peripheral circuit structure includes core peripheral circuits different than the memory cell array, and
the core peripheral circuits are connected to the internal power supply voltage line and the internal ground voltage line.
